(19) United States
(12) Patent Application Publication
(10) Pub. No.: US 2004/0107398 A1
(43) Pub. Date: Jun. 3, 2004

(54) Error detection in received data transmissions

(76) Inventor: Ian Robert Johnson, Bristol (GB)

Correspondence Address: LOWE HAUPTMAN GILMAN AND BERNER, LLP, 1700 DIAGONAL ROAD, SUITE 300 /310, ALEXANDRIA, VA, 22314, US

(21) Appl. No.: 10/611,423

(22) Filed: Jul. 2, 2003

(30) Foreign Application Priority Data
Jul. 2, 2002 (GB) GB 02152097.2

(51) Int. Cl. H03M 13/00

(52) U.S. Cl. 714/758

(57) ABSTRACT

An error correction method and apparatus passes received data onto higher system levels only if both a CRC check is determined to be valid and the forward error correction performed on the received data is determined to be valid.

### FIELD OF THE INVENTION

The present invention relates to a method of and apparatus for receiving data and more particularly to a receiver method and apparatus wherein an error in received data is detected.

### BACKGROUND OF THE INVENTION

It is well known in the field of data transmission to perform one or more checks on the received data to establish if the received data contains an error. One such example that is used when the data is transmitted in discrete data packets is a cyclic redundancy check (CRC). A cyclic redundancy check involves using the data to be transmitted to calculate a unique value associated with the data. Various methods of calculation are employed, ranging from simple binary addition of the data bits within the data to be transmitted to performing complex polynomial arithmetic on the data. Whatever calculation method is employed, the desired result is to achieve a unique CRC value associated with the data packet. The calculated CRC value is then appended to the data to be transmitted prior to transmission. At a receiver, an identical CRC calculation is performed on the received data, but not including the added CRC value. If no errors have occurred in the transmission of the data from the transmitter to the receiver, the CRC value calculated by the receiver is identical to the CRC value initially calculated by the transmitter and transmitted with the transmitted data. A simple comparison of the transmitted and calculated CRC at the receiver therefore indicates if any errors have occurred in the data during transmission.

Typically, a CRC value comprises 32 bits, thus providing 2³² possible unique CRC values. The probability of two different random data packets therefore having the same CRC value is equivalent to about 1 in 4,300 million. The probability of an error occurring in the received data and not being detected is therefore very small.

However, it is known that some data transmission protocols, for example Bluetooth™, use CRC values having less than 32 bits, for example 16 bits. A 16 bit CRC value only allows 2¹⁶, or approximately 65000 different CRC values to be generated. The number of errors that can occur within a data packet before the CRC value can be identical to the CRC value for the packet having no errors is referred to as the “minimum distance”. Clearly for a CRC value of only 16 bits, the minimum distance is much less than for a 32 bit CRC value. This means that a data packet need only contain a smaller number of errors before returning an apparently correct CRC value. Given the transmission rate for a system, such as Bluetooth™ combined with such a system having only a 16 bit CRC value, it is estimated that errors occurring in transmission wherein the CRC check is incorrectly regarded as correct could occur every few minutes. One application where such an error rate has a particularly detrimental impact is in the use of Bluetooth™ enabled printers. The occurrence of an error once every few minutes in data transmission from a Bluetooth™ enabled device to a suitably enabled printer can result in a significant probability that any given print job will not be completed because of an error occurring in the data transmission from the device to the printer. Of course other Bluetooth™ enabled devices, such as a wireless headset for a cellphone, may be more tolerant of such error levels, but nonetheless such an error rate is highly undesirable. The above examples of Bluetooth™ enabled devices are for illustration only and are not to be considered as limiting.

Other error control schemes are known to improve data transmission. A simple example of such a scheme is the use of an additional parity bit. The parity of the transmitted data is established prior to transmission and an additional parity bit is set accordingly. On receipt of the transmitted data, the parity is again determined and compared with the parity bit. Disagreement between the determined parity and the transmitted parity bit indicates that an error has occurred during transmission. Other, more complex error control schemes are known, such as a forward error correction codes. These involve coding the transmitted data such that on receipt of the transmitted data, any errors that have occurred during transmission are detected and/or corrected. An example of such a forward error correction scheme is convolution encoding with Viterbi decoding. A common characteristic of forward error correction codes is that redundant data is added to the data to be transmitted that allows the errors to be detected and corrected. Returning to the previous example of Bluetooth™ data transmission, a 15:10 forward error correction code is employed i.e. 15 bits are transmitted to send 10 bits of actual data.

However, if the transmitted data contains more than a certain number of errors, the number of errors being dependent upon the particular forward error correction code being used, the forward error correction code can fail because it becomes impossible to determine unique corrections for the data, and incorrect data bits may be left uncorrected whilst “correct” bits may be altered by the correction scheme. This failure can be detected by re-encoding the received data after the forward error correction has been applied to it and comparing the re-encoded data with the originally received transmitted data to determine the number of “errors” that have been “corrected” i.e. by determining the number of bits within the data that have been changed. A large number of “corrections” is an indication that the forward error correction code has failed.

An example of a similar technique is disclosed in the U.S. Pat. No. 6,163,571, which discloses a signal processing circuit for a receiver in a digital wireless communication system that uses a re-encode and compare scheme to measure received signal quality. Packets of data bits that have passed a CRC check are re-encoded and are compared to the originally received data to determine the number of bits that have been changed by the forward error correction scheme. This provides an estimate of the received signal quality. The data is subsequently forwarded for further processing. However, this system always operates on the assumption that both the CRC check and the forward error correction are accomplished accurately.

For data transmission systems where the probability of errors occurring in the data transmission is relatively high, and in particular when only a relatively small CRC value is used, neither a CRC check nor forward error correction coding provides a wholly reliable indication of the validity of a particular transmitted data packet.

### SUMMARY OF THE INVENTION

According to a first aspect of the present invention a method of receiving data comprises performing error correction on received data and determining if the error correction has failed. The failure of the error correction is determined according to at least one parameter of the received data changed by the error correction. A CRC value associated with the error corrected received data is calculated. Received data having a valid associated CRC value are rejected if the error correction has failed.

It is therefore possible to discard received data even though that data may have a valid CRC value, on the basis that an additional check on the likelihood of failure of the error correction is also conducted. In other words, the CRC check is double checked using a further check on the performance of the error correction scheme.

Preferably, the at least one parameter is the number of bits changed during error correction. More particularly, the error correction is determined as having failed when the number of changed bits in a block of data exceeds a threshold value.

Preferably, the number of changed bits is determined by re-encoding the corrected data and comparing the re-encoded data with the originally received data.

Preferably, the error correction is performed in accordance with a forward error correction code.

Additionally, the received data is rejected if the CRC value associated with the received data is not valid.

Preferably, the received data is in data packet format. More preferably the received data comprises at least one Bluetooth™ data packet.

According to a second aspect of the present invention a method of testing the validity of data received at a receiver comprises: performing an error correction routine on the received data; calculating a CRC value from the error corrected received data; if the CRC value is valid, determining the number of errors in the received data that have been corrected during the error correction routine; comparing the number of corrected errors with a predetermined threshold value; and if the number of corrected errors exceeds the predetermined threshold value, rejecting the received data as invalid, regardless of the validity of the CRC value.

According to a third aspect of the present invention a method of determining the validity of a received Bluetooth™ data packet receiver comprises: decoding the received data packet utilising an error correction decoder to generate an error corrected data packet; calculating a CRC value from the error corrected data packet and determining if the calculated CRC value is valid; re-encoding the error corrected data packet and comparing the re-encoded error corrected data packet with the received data packet to determine the number of errors in the received data corrected during decoding; and rejecting the received data packet as invalid if the number of determined errors exceeds a threshold value, regardless of the validity of the CRC value.

According to a fourth aspect of the present invention a receiver is arranged to (1) perform error correction on received data and (2) determine if the error correction has failed. The failure of the error correction is determined according to at least one parameter of the received data changed by the error correction. The receiver is also arranged to calculate a CRC value associated with the received data and to reject received data having a valid associated CRC value if the error correction has failed.

The at least one parameter may comprise the number of bits changed during error correction. Additionally, the receiver may determine that the error correction has failed in response to the number of changed bits exceeding a threshold value.

Additionally or alternatively, the receiver may comprise an encoder arranged to re-encode the received data and a comparator arranged to compare the re-encoded data and the received data, whereby the number of changed bits is determined.

Preferably, the receiver is arranged to perform forward error correction.

Additionally, the receiver may be further arranged to reject the received data if the associated CRC value is not valid.

Additionally, the receiver may be arranged to receive wireless data transmissions.

Preferably, the receiver comprises a Bluetooth™ enabled receiver.

According to a fifth aspect of the present invention a receiver comprises: error correction means for correcting errors in a received data packet; error counting means arranged to determine the number of errors in the received data packet corrected by the error correction means; error test means arranged to compare the number of corrected errors with a predetermined threshold value and to denote the received data packet as invalid if the number of corrected errors exceeds the threshold value; cyclic redundancy check value generating means for calculating a cyclic redundancy check value from the error corrected received data packet; and means for denoting the received data packet as invalid only if both the cyclic redundancy check value is valid and the error test means denotes the received data packet as valid.

According to a sixth aspect of the present invention a Bluetooth™ enabled receiver comprises: an error correction decoder for decoding a received data packet utilising error correction; a re-encoder for re-encoding the decoded data packet; an error counter for comparing the received data packet and the re-encoded data packet to determine the number of errors in the received data packet corrected by the error correction decoder; a CRC value calculator for calculating a CRC value from the decoded data packet; a CRC tester for determining the validity of the CRC value received from the CRC value calculator; and an error correction tester which, in response to the CRC tester determining the CRC value for the data packet to be valid, determines if the number of errors corrected by the error correction decoder exceeds a predetermined threshold value, the received data packet being rejected if the threshold value is exceeded.

According to a seventh aspect of the present invention a wireless communication enabled device comprises a receiver, in accordance with the fourth aspect of the present invention.

Preferably, the wireless communication enabled device comprises a Bluetooth™ enabled device, such as a printer, headset, loudspeaker or camera, computer, computer peripheral device, telephone, personal digital assistant, or other data processor. This list is not to be considered as exhaustive.

### BRIEF DESCRIPTION OF THE DRAWINGS

Embodiments of the present invention will be described, by way of example only, in conjunction with the accompanying figures, of which:

FIG. 1 is a schematic diagram of a prior art receiver; and

FIG. 2 is a schematic diagram of a receiver according to an embodiment of the present invention.

### DETAILED DESCRIPTION OF THE DRAWINGS

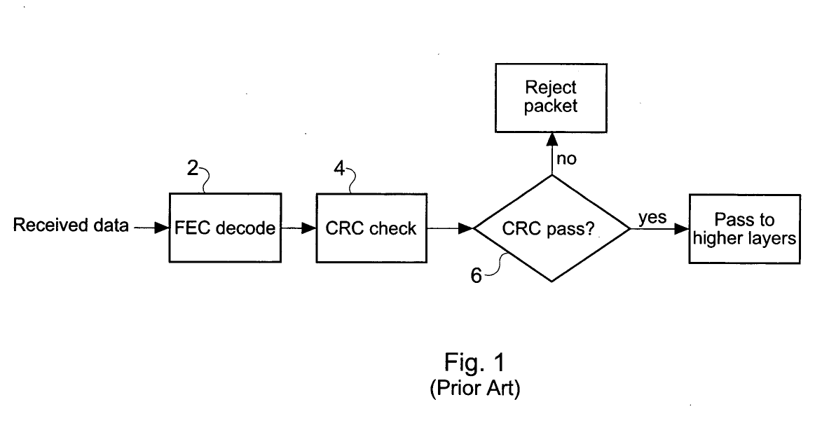

FIG. 1 is a schematic diagram of a prior art receiver. Received data is supplied to a forward error correction (FEC) decoder 2 that is arranged to perform a forward error correction on the received data, thereby correcting any errors that have occurred in the transmission of the data. It will be appreciated that the received data may be demodulated as appropriate before being supplied to the forward error correction decoder 2. The output of the forward error correction decoder 2 comprising the corrected data is supplied to a cyclic redundancy check (CRC) checker 4. The CRC checker 4 calculates the associated CRC value and outputs both the calculated value and the value transmitted with the received data to a CRC tester 6. The CRC tester 6 compares the transmitted CRC value with that calculated by the CRC checker 4. If the two values are not equal the CRC tester 6 rejects the received packet. If the two CRC values are equal, indicating that the data has been successfully transmitted, then the data packet is passed onto further parts of the system connected to the receiver.

Where receivers of this type are used with data transmission protocols having a relatively small CRC check value, for example Bluetooth™ that has a 16 bit CRC value, the receiver is prone to incorrectly passing the data packet onto the higher layers. This occurs for received data containing a significant number of errors because the forward error correction decoder 2 cannot successfully correct the errors, although it gives an indication that it has. Incorrect data is therefore passed to the CRC checker 4. As the CRC is only a 16 bit value, the probability of data having a significant number of errors generating a CRC value that nonetheless is identical to the correct CRC value is relatively high (around 1 in 60,000). The CRC tester 6 will therefore determine that the calculated CRC is correct because it matches the transmitted CRC, even though in reality the data is not valid, and will pass the erroneous data to higher levels within the system.

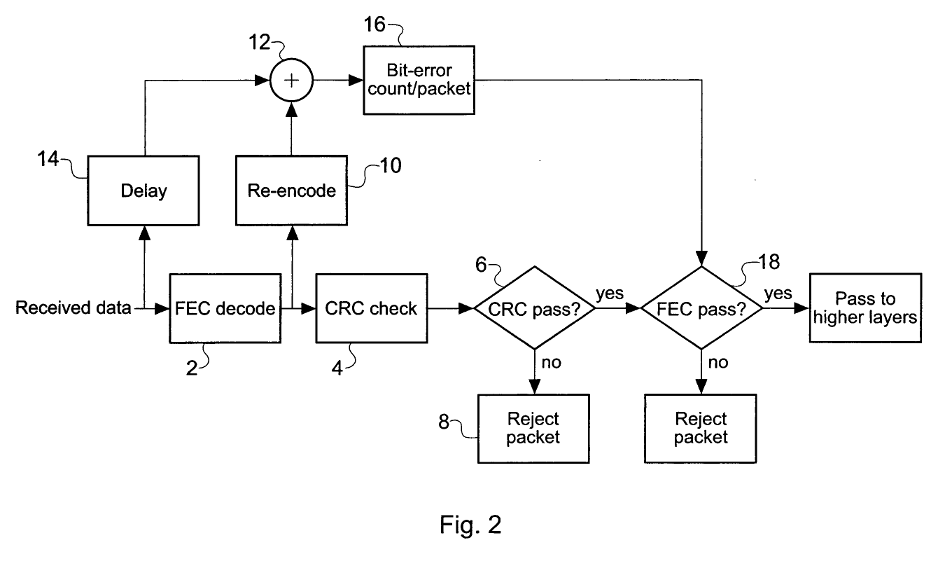

FIG. 2 is a schematic diagram of a receiver system according to an embodiment of the present invention. Where applicable, like elements are given like reference numerals. Received data is supplied to a forward error correction decoder 2 that performs error correction on the received data in an attempt to correct any errors that have occurred during transmission. The corrected data is derived from the forward error correction decoder 2 and supplied to a CRC check sum unit 4. The CRC check sum unit 4 calculates the associated CRC value of the corrected data and passes the calculated CRC value to a CRC tester check unit 6 that compares the calculated CRC value with the CRC value transmitted with the data. If the two CRC values are not equal, the CRC tester 6 determines that the received data is not valid and rejects the data packet. The corrected data at the output of the forward error correction decoder 2 is also supplied to a re-encoder 10 that re-encodes the corrected data using the same code as employed for transmission of the data by the transmitter. The re-encoded data is supplied by the re-encoder 10 to a comparator 12. In addition to being supplied to the forward error correction decoder 2, the received data is also supplied to the comparator 12 via a delay block 14, having a delay time equal to the processing times of decoder 2 and re-encoder 10 so corresponding bits simultaneously arrive at the inputs of comparator 12. The comparator 12 performs a bit by bit comparison between the originally received data and the corrected and re-encoded data to determine if any differences exist. The number of differences is determined by a bit error counter 16 and provides an indication of the number of “errors” that have been “corrected” by the forward error correction decoder 2 in a given packet of data. The output of the bit error counter 16 is supplied to a forward error correction tester 18 that uses the number of errors to determine whether the forward error correction has in fact failed or not. The forward error correction tester 18 receives the corrected data from the output of the CRC tester 6. If the forward error correction tester 18 determines that the error correction has failed because the number of corrections exceeds a threshold, then the received data is rejected. If tester 18 determines that both the CRC value is valid and that the forward error correction is valid, then the received data is supplied by the forward error correction tester 18 to higher levels of the system.

The advantage of the receiver system according to the above described embodiment of the present invention is that in addition to the CRC value being checked, which may provide an erroneous indication of a valid CRC because of the use of a relatively small number of bits for the CRC value, for example 16 bits in Bluetooth™ applications, a further check is performed based on the determined validity of the forward error correction. In effect, the validity of the forward error correction is used as a double check on the validity of the CRC check.

It is envisaged that embodiments of the present invention are particularly applicable to wireless data transmission, for example Bluetooth™ systems, such as wireless connectivity between Bluetooth™ enabled devices. Bluetooth™ is given as an example because Bluetooth™ transmission may be subject to a significant number of errors. This is due to a number of factors, one of which is the use of only a 16 bit CRC check value that allows as previously discussed, an increase probability of an apparently correct check sum being generated from data containing a significant number of errors. Additionally, Bluetooth™ is transmitted within the 2.4 GHz transmission band that is available for any other transmission systems at this frequency. The transmission channel may therefore be of low quality due to relatively high interference from other sources. The channel is also susceptible to poor transmission quality because of interference resulting from multiple path transmissions where the wireless transmission reflects off objects within the transmission channel to create reflected additional transmissions that can interfere with the originally transmitted signal. The applications using Bluetooth™ and which can have their error performance improved by use of embodiments of the present invention include Bluetooth™ enabled printers.

1. A method of receiving data comprising:
performing error correction on received data;
determining if the error correction has failed, the failure of the error correction being determined according to at least one parameter of the received data being changed by the error correction;
determining a CRC value associated with the error corrected received data; and
rejecting received data that has a valid associated CRC value if the error correction has failed.

2. A method according to claim 1, wherein the at least one parameter comprises the number of bits changed in the received data during the error correction.

3. A method according to claim 2, wherein the error correction is determined as having failed when the number of changed bits exceeds a threshold value.

4. A method according to claim 2, wherein the number of changed bits is determined by re-encoding the corrected data and comparing the re-encoded data to the originally received data.

5. A method according to claim 1, wherein the error correction is performed in accordance with a forward error correction code.

6. A method according to claim 1, wherein the received data is rejected if the CRC value is not valid.

7. A method according to claim 1, wherein the received data conforms to a wireless transmission protocol.

8. A method according to claim 1, wherein the received data is in data packet format.

9. A method according to claim 1, wherein the received data comprises at least one Bluetooth™ data packet.

10. A method of testing the validity of data received at a receiver, the method comprising:
performing an error correction routine on the received data;
calculating a CRC value from the error corrected received data;
if the CRC value is valid, determining the number of errors in the received data that have been corrected during the error correction routine; and
comparing the number of corrected errors with a predetermined threshold value and if the number of corrected errors exceeds the predetermined threshold value rejecting the received data as invalid, regardless of the state of the CRC value.

11. A method of determining the validity of a Bluetooth™ data packet received at a Bluetooth™ enabled receiver, the method comprising:
decoding the received data packet utilising an error correction decoder to generate an error corrected data packet;
calculating a CRC value from the error corrected data packet;
determining the state of the calculated CRC value;
re-encoding the error corrected data packet;
comparing the encoded error corrected data packet with the received data packet to determine the number of errors in the received data corrected during decoding; and
rejecting the received data packet as invalid if the number of determined errors exceeds a threshold value, regardless of the state of the CRC value.

12. A receiver arranged to perform error correction on received data and to determine if said error correction has failed, the receiver having arranged to determine the failure of said error correction in response to at least one parameter of the received data being changed by the error correction, the receiver being further arranged to calculate a CRC value associated with the received data and to reject received data having a valid associated CRC value in response to said error correction having failed.

13. A receiver according to claim 12, wherein the at least one parameter comprises the number of bits changed in the received data during error correction.

14. A receiver according to claim 13, wherein the receiver is arranged for determining that the error correction has failed in response to the number of changed bits exceeding any threshold value.

15. A receiver according to claim 13, wherein the receiver comprises an encoder arranged to re-encode the received data and a data comparator arranged to compare the re-encoded data and the received data, for determining the number of changed bits.

16. A receiver according to claim 12, wherein the receiver is arranged to perform forward error correction.

17. A receiver according to claim 12, wherein the receiver is further arranged to reject the received data if the associated CRC value is not valid.

18. A receiver according to claim 12, wherein the receiver is arranged to receive wireless data transmissions.

19. A receiver according to claim 12, wherein the receiver comprises a Bluetooth™ enabled receiver.

20. A receiver comprising:
error correction means for correcting errors in a received data packet;
error counting means for determining the number of errors in the received data packet corrected by the error correction means;
error test means for comparing the number of corrected errors with a predetermined threshold value and for denoting the received data packet as invalid in response to the number of corrected errors being determined to exceed the threshold value;
cyclic redundancy check value generating means for calculating a cyclic redundancy check value from the error corrected received data packet; and
means for denoting the received data packet as invalid only if both the cyclic redundancy check value is determined to be valid and the error test means denotes the received data packet as valid.

21. A Bluetooth™ enabled receiver comprising:
an error correction decoder for decoding a received data packet utilising error correction;
a re-encoder for re-encoding the decoded data packet;
an error counter for comparing the received data packet and the re-encoded data packet to determine the number of errors in the received data packet corrected by the error correction decoder;
a CRC value calculator for calculating a CRC value from the decoded data packet;
a CRC tester for determining the validity of the CRC value received from the CRC value calculator; and
an error correction tester for determining if the number of errors corrected by the error correction decoder exceeds a predetermined threshold value, the tester being arranged for making the determination in response to the CRC tester determining the CRC value for the data packet being valid, the error correction tester being arranged to reject received data packet if the threshold value is exceeded.

22. A wireless communication enabled device comprising a receiver according to claim 12.

23. A Bluetooth™ enabled device comprising a Bluetooth™ receiver according to claim 20.
